(19) United States
(12) Patent Application Publication
(10) Pub. No.: US 2014/0217540 A1
(43) Pub. Date: Aug. 7, 2014

(54) FULLY DEPLETED DIODE PASSIVATION ACTIVE PASSIVATION ARCHITECTURE

(71) Applicant: TELEDYNE SCIENTIFIC & IMAGING, LLC, Thousand Oaks, CA (US)

(72) Inventors: WILLIAM E. TENNANT, Thousand Oaks, CA (US); DONALD L. LEE, Thousand Oaks, CA (US); ERIC C. PIQUETTE, Camarillo, CA (US)

(73) Assignee: TELEDYNE SCIENTIFIC & IMAGING, LLC, Thousand Oaks, CA (US)

(21) Appl. No.: 13/758,255

(22) Filed: Feb. 4, 2013

(51) Int. Cl. H01L 33/28; H01L 27/15

(52) U.S. Cl. CPC H01L 33/28; H01L 27/15
USPC 257/437; 257/461; 257/443; 438/95

(57) ABSTRACT

A fully depleted “diode passivation active passivation architecture” (DPAPA) produces a photodiode structure which includes a substrate, a highly-doped buffer layer of a first carrier doping type above the substrate, a low-doped or undoped semiconductor active layer of the first carrier doping type above the buffer layer, a low-doped or undoped passivation layer above the active layer, the passivation layer having a wider band gap than the active layer; and a junction layer of a carrier doping type opposite the first carrier doping type above the passivation layer such that a pn junction is formed between the junction layer and the passivation and active layers, the junction creating a depletion region which expands completely through the passivation and active layers in response to a reverse bias voltage. The fully depleted structure substantially eliminates Auger recombination, reduces dark currents and enables cryogenic level performance at high temperatures.

### BACKGROUND OF THE INVENTION

1. Field of the Invention

This invention relates generally to optoelectronic devices and, more particularly, to photodiode structures.

2. Description of the Related Art

Photodetectors are used in numerous applications to detect light and provide a corresponding electrical signal. Infrared (IR) photodetectors are one class of detectors which are employed in a variety of applications, such as night vision, communications, and environmental monitoring. IR detectors can be based on several different material systems, including silicon (Si), gallium arsenide (GaAs), silicon germanium (SiGe), aluminum gallium arsenide (AlGaAs), indium arsenide antimonide (InAsSb), indium gallium arsenide (InGaAs), superlattices (including Type II and Type III and including strain in the structure), lead salts (PbS, PbSeTe, PbSnTe, PbSnSe, PbSeTe), various Hg-bearing compounds, pseudobinary alloys of HgTe and HgSe with CdTe, CdSe, MnTe, MnSe, ZnTe, and ZnSe. Mercury cadmium telluride (HgCdTe or MCT) is attractive because it has a direct energy gap, can be grown as high-quality epitaxial thin films on transparent substrates, can be doped to obtain both high and low carrier concentrations, and spans the entire IR wavelength range from ˜0.8 μm to >20 μm. It can also be compositionally graded to vary the band gap energy with position. More information regarding MCT photodetectors can be found, for example, in U.S. Pat. No. 6,034,407.

Photodiodes provide the highest performance of all photodetectors. A photodiode consists of a semiconductor pn junction. The semiconductor absorbs light having photon energy higher than the semiconductor's band gap, creating electron-hole pairs. If the light is absorbed in the n(p)-region, the holes (electrons) are the minority carriers and diffuse to the depletion region, where they are swept by the depletion region electric field into the p(n)-region to create a photocurrent that becomes the detector signal. Absorption of light in the depletion region produces this sweeping without need for diffusion.

The fundamental quality of a detector is its signal-to-noise ratio (SNR); i.e., the ratio of the photocurrent to the noise current present in the detector under measurement conditions. The highest quality a detector can have in any operating condition is to have a SNR limited by the noise current that comes from the photon background itself. This condition is called “background-limited performance” or BLIP. The highest BLIP quality is attained when every absorbed photon generates a minority carrier that contributes to the photocurrent. The efficiency of minority carrier collection is called the quantum efficiency, and perfect detectors will have a quantum efficiency of 1. Note that if the light is absorbed in a material of relatively low band gap, but the pn-junction is in a portion of the semiconductor structure with a wide band gap (i.e., if the structure is a type of “heterostructure” having spatially varying energy gaps), an energy barrier may exist that frustrates diffusion of minority carriers to the depletion region and significantly reduces the photocurrent.

The best current MCT detector technology with cut-off wavelengths longer than about 4.6 μm operates near its full potential. That is, the detector dark currents appear to be primarily due to fundamental “Auger” generation mechanisms, which are properties of the crystal's inherent electronic structure. In general, dark currents are caused by this fundamental mechanism, as well as by residual point and extended defects in the material. Current-generating defects can be impurities or vacancies, imperfect surfaces or interfaces, or damage introduced during growth or device fabrication. In addition to causing unwanted dark currents, these defects can cause minority carriers to recombine, including those photogenerated carriers that produce the detector signal. This recombination decreases the detector quantum efficiency.

The defects mentioned above may also cause the detectors to have too much noise. Dark current, which is the current that flows through the photodetector in the absence of incident light, adds noise to that inherent in the photocurrent, lowering the SNR below the BLIP level. The dark current is caused by the thermal generation or tunneling of charge carriers due to fundamental mechanisms, to point defects, or to extended defects. It is generally desired to have the photodetector provide its maximum (BLIP) sensitivity at as high at temperature as possible, up to room temperature or above, to avoid the need for elaborate cooling schemes. However, the thermally generated dark current-induced noise typically increases exponentially with increasing operating temperature.

A heterojunction photodiode described in U.S. Pat. No. 7,368,762 is designed to mitigate the process-related dark currents and associated noise due to near junction defects and imperfect surfaces which typically reduce photodiode device performance. This is done by placing the p-n junction in a wide band gap layer of the structure, where defects cannot generate dark currents as readily. The structure also eliminates Auger recombination, a fundamental source of dark current, by depeleting the structure of free carriers which facilitate the Auger generation mechanism.

Although the structure described in U.S. Pat. No. 7,368,762 can in principle mitigate both fundamental and defect-generated photodiode dark current sources, the fully depleted structure poses some significant problems for fabrication. In particular, to extend the depletion region completely through the active layer requires having a layer that is thin enough to be depleted with attainable doping and voltage biases, but thick enough to absorb incident radiation effectively. Moreover, in an array format, individual diodes need to be placed close enough together to allow the lateral extension of the depletion region of each diode to touch or merge with the depletion region of the neighboring diodes throughout the active layer and potentially some nearby wider gap layers that may contribute dark currents. Thus, the need for full depletion requires a relatively close positioning of neighboring diodes as well as a relatively thin active layer. The exact spacing and active layer thickness of the diodes will depend on doping and bias attainable as well as the absorption properties and band gap of the active material. Typical values for long wave infrared (LWIR) mercury cadmium telluride (HgCdTe) may be on the order of 1-3 μm for both active layer thickness and diode separation distance.

### SUMMARY OF THE INVENTION

A fully depleted “diode passivation active passivation architecture” (DPAPA) is presented which addresses several of the problems noted above, enabling the production of photodiodes having greatly reduced dark currents using a simplified fabrication process.

The present DPAPA architecture produces a photodiode structure which includes:
a substrate;
a first passivating buffer layer of a first carrier doping type (n or p) above the substrate and which is highly-doped through part or all of its thickness;
a low-doped or undoped semiconductor active layer of the first carrier doping type above the buffer layer;
a low-doped or undoped second passivation layer above the active layer, the passivation layer having a band gap energy graded over at least part of its thickness from that of the active layer to a larger energy; and
a junction layer of a second carrier doping type (p or n) opposite the first carrier doping type above the second passivation layer such that a pn junction is formed between the junction layer and the second passivation and active layers, the junction creating a depletion region which expands completely through at least the passivation and active layers in response to a reverse bias voltage.
   The fully depleted structure substantially eliminates Auger recombination, reduces dark currents and enables cryogenic level performance at high temperatures. The placing of the electrical junction on the top of the wide-band-gap second passivation layer eliminates the need for a separate passivation deposition, minimizes tunneling by placing the highest field region in a wide band gap material, and allows ease of processing of close-spaced pixels as required for full depletion in arrays.

As is known by those skilled in the art, the structure may be made lattice-matched, or nearly lattice-matched by the appropriate addition of small amounts of Mn, Zn, Se, S, or other elements from columns II and VI of the periodic table. Lattice-matching reduces the formation of dislocations, which may contribute to dark currents. The buffer, active, passivation and junction layers are preferably formed by molecular beam epitaxy (MBE) or another growth technique such as metal organic vapor phase epitaxy, liquid phase epitaxy, and solid state recrystalization, which serves to increase operability and yield while simplifying the fabrication process. The substrate may be removed after the layers are formed, such that the buffer layer serves as the layer through which light enters as well as a first passivation layer for the side of the active layer opposite the junction.

The second passivation layer and said active layer are preferably arranged such that the largest band gap energy of the second passivation layer is at least twice that of the active layer, which operates to ensure that the passivation layer does not contribute to dark currents.

The grading of the second passivation layer is preferably arranged such that the minority carriers have no barrier to their transport under operating bias, and do not become trapped in local energy minima in the minority carrier band. With appropriate grading and junction properties known to those skilled in the art, the bias sufficient to deplete the active layer will be more than sufficient to insure good minority carrier transport and to avoid minority carrier trapping. Note that in some semiconductor systems, this grading may be partly achieved during the various high-temperature processing steps (for instance the junction activation anneal) which occur during the normal course of diode fabrication.

These and other features, aspects, and advantages of the present invention will become better understood with reference to the following drawings, description, and claims.

### BRIEF DESCRIPTION OF THE DRAWINGS

FIG. 1 is a simplified diagram of an imaging system in accordance with the present invention.

FIG. 2 is a simplified sectional view of a photodiode structure in accordance with the present invention.

FIG. 3 is a simplified sectional view of a photodiode structure in accordance with the present invention, and a graph showing the energy bands across the device structure under various bias conditions for the photodiode structure shown in FIGS. 2 and 3.

FIG. 4 is a simplified sectional view of a four adjacent photodiode structures in accordance with the present invention.

FIG. 5 is a simplified sectional view of four adjacent photodiode structures in accordance with an alternative embodiment of the present invention.

### DETAILED DESCRIPTION OF THE INVENTION

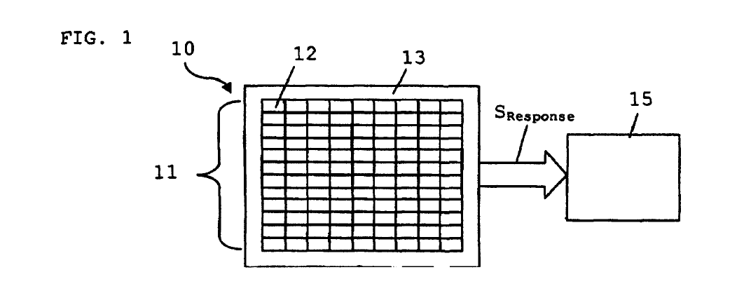

FIG. 1 is a simplified top view of an imaging system 10 which includes an array 11 of pn or Schottky-barrier photodiodes 12 (interchangeably referred to herein as “photodetectors”). The photodetectors in array 11 are formed on a substrate 13, although they could be formed individually and mounted on a support structure. System 10 can be included, for example, in a focal plane array (FPA), which is an optical sensor placed at the focal plane of an optical system such as a camera, spectrometer, or telescope. In these applications, the FPA is typically sensitive to ultraviolet, visible, or infrared radiation, although other wavelengths may also be detected.

System 10 would typically include circuitry 15 coupled to array 11. Circuitry 15 could include a read-out integrated circuit (ROIC) or a multiplexer which provides electronic access to the photodiodes in array 11. In response to the image detected, array 11 provides a signal S_{Response} to circuitry 15 for image processing. Circuitry 15 can be external to system 10, or can be integrated with other components on substrate 13, such as array 11.

The junctions of photodiodes 12 can be formed as pn junctions by numerous well-known methods, including ion implantation, diffusion doping, or by doping during growth. Alternatively, they can be formed as Schottky-barrier junctions by depositing any of several metals or semi-metals on the heterostructure; for n-type absorbers and passivation, suitable metals would be ones with a large work function, such as Au, Pt, Pd, or other metals known to those in the field. Semi-metals such as HgTe may also make appropriate Schottky barriers. For p-type absorbers and passivation, a lower work function Schottky barrier material would be preferred.

As noted above, there are many factors which can act to degrade the performance of a photodiode, including process-related dark currents and associated noise due to near-junction defects, Auger recombination, etc. Photodiode structures produced in accordance with the present DPAPA architecture mitigate several of these problems. The present photodiode structure (discussed in detail below) includes a substrate, a first passivating buffer layer of a first carrier doping type (n or p) above the substrate which is highly-doped for at least an initial part of its thickness and which may be graded from a wide band gap to a narrower band gap with increasing distance from the substrate, a low-doped or undoped semiconductor active layer of the first carrier doping type above the buffer layer, a low-doped or undoped second passivation layer above the active layer, the second passivation layer being graded from the energy gap of the active layer to a larger band gap than the active layer, and a junction layer of a second carrier doping type (p or n) opposite the first carrier doping type or a metal layer above the second passivation layer such that a pn or Schottky-barrier junction is formed which creates a depletion region that expands completely through at least the second passivation and active layers in response to a reverse bias voltage. The fully depleted structure substantially eliminates Auger recombination, reduces dark currents and enables cryogenic level performance at high temperatures. The placing of the electrical junction on the top of the wide-band-gap second passivation layer eliminates the need for a separate passivation deposition, minimizes tunneling by placing the highest field region in a wide band gap material, and allows ease of processing of close-spaced pixels as required for full depletion in arrays.

The grading of the second passivation layer is preferably arranged such that the minority carriers have no barrier to their transport under operating bias, and do not become trapped in local energy minima in the minority carrier band. With appropriate grading and junction properties known to those skilled in the art, the bias sufficient to deplete the active layer will be more than sufficient to insure good minority carrier transport and to avoid minority carrier trapping. Note that in some semiconductor systems, this grading may be partly achieved during the various high-temperature processing steps (for instance the junction activation anneal) which occur during the normal course of diode fabrication.

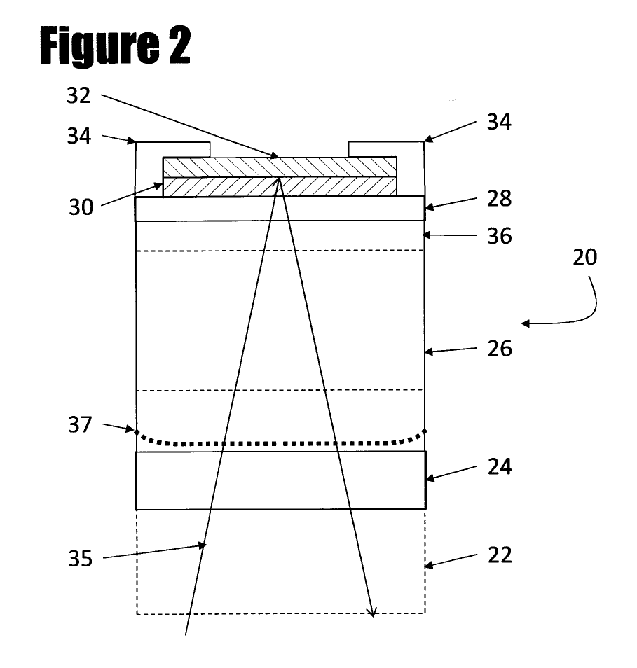

FIG. 2 is a simplified sectional view of a photodiode structure 20 in accordance with the present invention. The structure is formed on a substrate 22 which may be removed after the primary device layers are formed (discussed below). A first highly-doped passivating buffer layer 24 of a first carrier doping type (n or p) is above substrate 20, a low-doped or undoped semiconductor active layer 26 of the first carrier doping type is above buffer layer 24, a low-doped or undoped second passivation layer 28 is above active layer 26, and a junction layer 30 of a carrier doping type (p or n) opposite the first carrier doping type is above second passivation layer 28 such that a pn junction is formed between junction layer 30 and the second passivation and active layers. Second passivation layer 28 and active layer 26 are arranged such that the second passivation layer is graded from the active layer to a wider band gap than the active layer—preferably, the relationship between the largest band gap energy of the second passivation layer E_{g(pass)} and that of the active layer E_{g(active)} is such that E_{g(pass)}>2*E_{g(active)}. This band relationship insures that currents generated by mid-gap states in the surface of the passivation layer will drop on cooling faster than fundamental active layer currents, helping to insure that the active layer dominates device performance. When properly arranged, the pn junction creates a depletion region which expands completely through at least second passivation layer 28 and active layer 26 in response to a reverse bias voltage.

The device structure would typically also include a metal contact 32 on junction layer 30, and an environmental overcoat structure 34 to make the device more robust. Photodiode 20 is back illuminated so that light 35 incident on the lower surface of buffer layer 24 (through an optically transparent substrate 22, if present, which may be anti-reflection coated to improve transmission) is reflected by contact 32. A cap layer 36 might also be included between second passivation layer 28 and active layer 26, to increase the efficiency with which carriers are transported.

As noted above, buffer layer 24 and active layer 26 are of a first carrier doping type, and the junction layer is of the opposite carrier doping type. The following discussion of the layers assumes an exemplary embodiment in which the buffer and active layers are n-type and the junction layer is p-type, though an embodiment in which the buffer and active layers are p-type and the junction layer is n-type is equally valid, as might be devices based on material systems other than those referred to below.

The device layers are preferably formed as follows: buffer layer 24 is a highly-doped n-type HgCdTe layer with appropriate amounts of Zn, Se, Mn, or other Group II or Group VI materials added to reduce lattice mismatch and misfit dislocations, as is known to those familiar with the art. Passivating buffer layer 24 is graded to a thin (˜1-3 μm) low-doped active layer 26, which is graded through a thin (˜500 nm) low-doped n-type cap layer 36 (if present), which is graded through to a thin (˜200 nm) low-doped CZT passivation layer 28. Second passivation layer 28 is then preferably graded to a p+ doped junction layer 30, which is in contact with metal contact layer 32. Junction layer 30 may be grown on or implanted into second passivation layer 28. Optional environmental overcoat layer 34 is preferably a thin insulating layer of Si₃N₄, ZnS, or other material such as typically used by those skilled in the art. Those knowledgeable in the art may find that a different ordering of the deposition of the overcoating layer and the metal contact layer is preferable for some applications.

After hybridization to a readout integrated circuit (ROIC) to create a sensor chip assembly (SCA) sometimes called a focal plane array (FPA), substrate 22 is preferably removed from the buffer, active, passivation and junction layers, such that buffer layer 24 serves as a passivation layer—thereby realizing the DPAPA architecture.

A typical practical application includes an array of photodiodes as described herein, arranged such that the second passivation and active layers are fully depleted both vertically and laterally when the reverse bias voltage is greater than a predetermined value. The individual pn junctions are preferably isolated by etching through junction layer 30 but not through second passivation layer 28, prior to or after anneal. If necessary, the junctions may be activated—by heating, for example—either before or after delineation. If before, metallization can be used as a mask for mesa etch. Junctions in close proximity will have overlapping depletion regions, thereby preventing conduction between diodes. The reverse bias voltage required to deplete the structure is given approximately by V=L² q N/2 εε₀, where V is the applied voltage plus the built-in voltage of the pn junction, L is the distance from the pn junction (assumed to be heavily doped on the p-side) to the farthest extent of the active layer, q is the electronic charge, N is the doping density on the n-side of the junction including the active layer, e is the relative static dielectric constant of the depleted region of the semiconductor, and ε₀ is the dielectric permittivity of free space. For L=1.5 μm, N=3×10¹⁴, and ε=15, V=0.47V.

The isolated photodiodes may be passivated with a wide-band-gap material deposited by evaporation or crystal growth or, as in the case of HgCdTe and other semiconductors for which interdiffusion is a possible processing tool, by indiffusion from a vapor or deposited layer of Cd and/or Zn, or other material appropriate to the semiconductor materials system used, to widen the surface band gap.

Photodiodes in accordance with the present architecture are preferably fabricated with the buffer, active, passivation and junction layers formed by one or more growth techniques selected from a group consisting of molecular beam epitaxy (MBE), metal organic vapor phase epitaxy, liquid phase epitaxy and solid state recrystalization. All of these growth techniques require the use of a substrate upon which the layers are grown, but as noted above, the substrate is preferably removed at some point in the process sequence after the layers are formed, most typically at the end after hybridization to a readout integrated circuit. Performing all critical junction formation steps with, for example, MBE, serves to simplify the fabrication process, provide higher junction integrity, and increase operability and yield. Further, growing the buffer layer in this way enables the substrate to be removed (and the buffer layer to serve as a backside passivation layer) with no need for any exotic backside treatments.

Conventionally, a passivation layer is located above a photodiode's junction layer. Locating second passivation layer 28 below junction layer 30 as described herein, referred to as ‘junction over passivation’, provides several advantages. One primary advantage is that this arrangement ensures that the highest field region, required by the relatively high biases associated with full depletion, occur in a wide band gap material which reduces the dark currents associated with tunneling. In addition, the need for a separate passivation step is eliminated, and passivation is brought under the control of the chosen growth technique.

Structures in accordance with the present architecture would typically also include an electrical contact (not shown, and typically outside the pixel area) with buffer layer 24, such that the buffer layer provides a return current path to the contact layer. The photodiode would then be biased by applying a potential difference between this contact and contact layer 32. The bias can be provided from, for example, circuitry 15 in FIG. 1, or from other external electronic circuitry (not shown). The return-current contacts preferably include metal which forms ohmic contacts to buffer layer 24 and junction layer 30. Alternatively, the contacts can form Schottky contacts or even forward-biased diodes with their respective contact regions.

Devices formed as described above provide simple low dark current photodetectors. Having the largest band gap energy of the passivation layer be at least two times wider than that of the active layer ensures that the passivation layer's band gap will be wide enough to prevent the layer from contributing to dark currents; the second passivation layer's material composition should also be such that conduction through the layer is allowed, under bias. The fully depleted structure reduces or eliminates Auger recombination, greatly reduces dark current, enables low drift-dominated cross-talk, and allows cryogenic-level performance at high temperatures.

As noted above, a device in accordance with the present architecture might alternatively include a Schottky-barrier junction instead of a pn junction. In this case, the layer above second passivation layer 28 would be a metal layer (not shown), such that a Schottky-barrier junction is formed between the metal layer and passivation and active layers 26 and 28, with the junction creating a depletion region which expands completely through at least both the second passivation and active layers in response to a reverse bias voltage. Note, however, that the performance of the present structure using a Schottky-barrier junction is likely to be worse that that of a pn junction-based device. For best performance, it may be necessary to increase the largest band gap of the passivation layer.

The present photodiode structure would typically be employed to form a detector array. The substrate, first passivating buffer layer, low-doped or undoped semiconductor active layer, low-doped or undoped second passivation layer and junction layer are as described above, except that here, an array of pn junctions (or Schottky-barrier junctions) are formed in the junction layer by reticulating the junction layer into pixels, either with an etch through the junction layer or by selective doping of regions of the junction layer with a dopant of the opposite type to isolate regions of the junction layer into separate diodes above the second passivation and active layers. When properly arranged, each of the junctions creates a depletion region which expands through at least the second passivation layer and the active layer and extends to the depletion region of all nearest and next nearest neighbor devices in response to a reverse bias voltage. A focal plane array (FPA) can be formed by adding a ROIC or other transducer to the detector array to turn the array-produced photocurrent into an electrical signal.

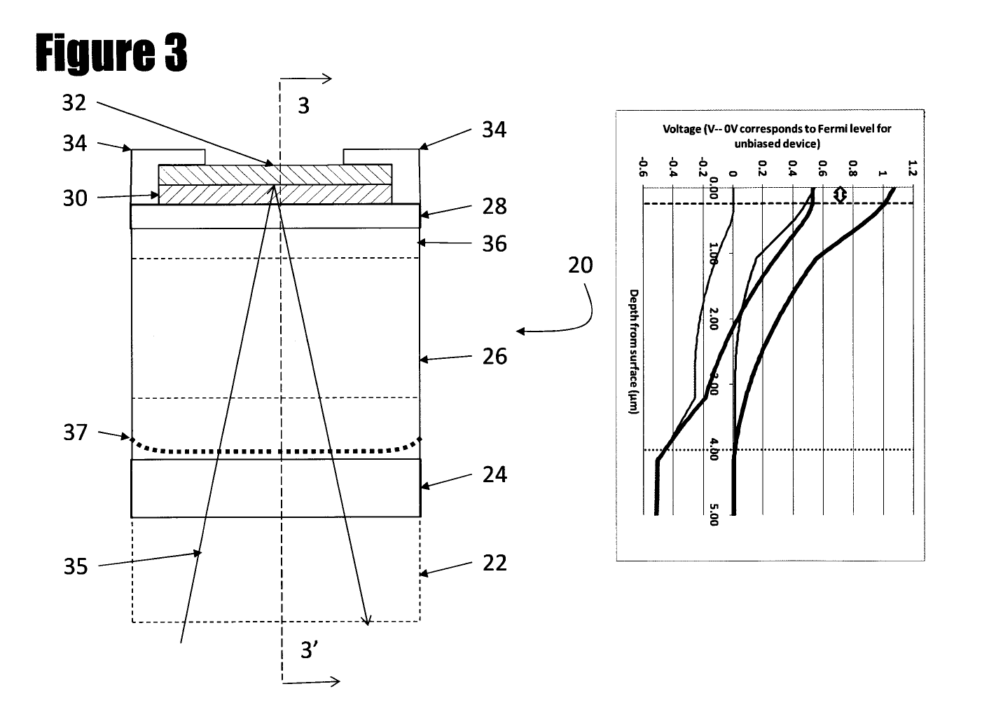

FIG. 3 includes the same simplified sectional view as FIG. 2, as well as a semiconductor band diagram along a cut line 3-3′ through the pn photodiode 20 aligned with regions 30, 28, 36, 26, and 24 of the sectional view. In the band diagram, both unbiased (gray lines) and −0.53 mV reverse bias (black lines) band conditions are shown. In each case the conduction band is represented by the thicker line on the band diagram and the valance band by the thinner line. The extent of the depletion region under bias (37) is shown on the sectional view.

In an energy band diagram, the band gap energy is the difference between the conduction band energy E_{c} and the valence band energy Eᵥ. In the diagram E_{F} is set at 0 volts. At zero bias the depletion region extends only part way through the structure and does not fully deplete the active layer. In HgCdTe and other mature IR semiconductors with few defect sources of dark current, the undepleted region of the active layer (the narrowest gap material) will contribute undesirable dark current through the Auger generation mechanism. If operated in this mode, the device will require lower temperatures to insure that the dominant currents are photocurrents. Also, with an undepleted region of the active absorber layer, carriers generated by light incident on one detector element may diffuse and be collected by a neighboring element, thereby producing undesirable cross-talk.

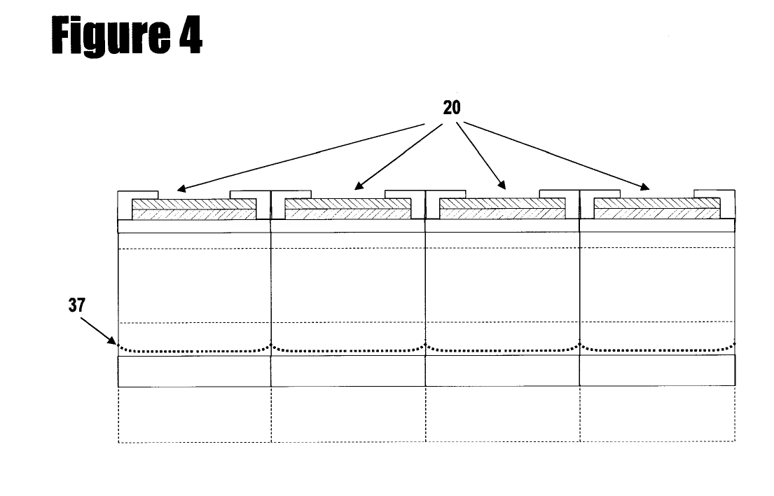

When the pn junction is sufficiently reverse biased to extend the depletion region fully through the active layer and laterally to merge with the depletion region of neighboring similarly reverse-biased diodes, the free carriers are eliminated from the active layer, reducing dark current, and diffusion is essentially eliminated, greatly reducing cross talk. This is illustrated in FIG. 4, which shows four adjacent diodes 20 under bias with depletion regions 37 continuous throughout the active region.

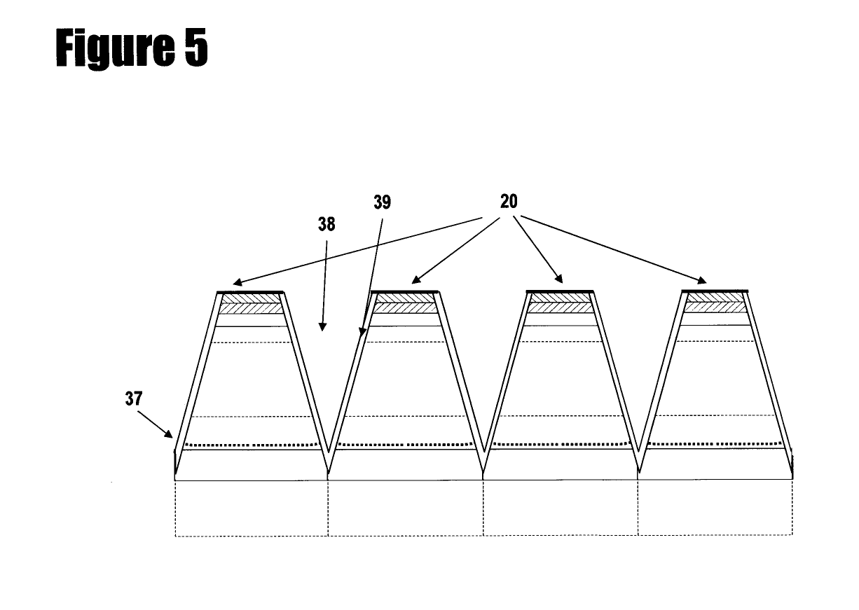

An alternative method of reticulating pixels is to extend the etch past the junction region through the entire active layer and into the highly-doped region of the buffer layer is illustrated in FIG. 5. This overcomes the possibility of inter-diode shorting by separating the active regions by a mesa trench 38, rather than relying on the lateral extension of the depletion region due to bias. It also allows for the reduction of the active collection area to a fraction of the reticulation distance (a feature that may be useful in some focal plane applications). Those knowledgeable in the art may realize that the sidewall of the mesa can be made easier to passivate by deposition of a wide-band-gap material by evaporation or crystal growth or, as in the case of HgCdTe and other semiconductors for which interdiffusion is a possible processing tool, by indiffusion from a vapor or deposited layer of Cd and/or Zn to widen the surface band gap. It also allows for separation of active diodes from one another, while retaining both their low doping and their small area properties.

The embodiments of the invention described herein are exemplary and numerous modifications, variations and rearrangements can be readily envisioned to achieve substantially equivalent results, all of which are intended to be embraced within the spirit and scope of the invention as defined in the appended claims.

1. A photodiode structure, comprising:
a substrate;
a first passivating buffer layer of a first carrier doping type (n or p) and which is highly-doped through part or all of its thickness above said substrate;
a low-doped or undoped semiconductor active layer of said first carrier doping type above said buffer layer;
a low-doped or undoped second passivation layer above said active layer, said second passivation layer having a band gap energy graded over at least part of its thickness from that of the active layer to a larger energy; and
a junction layer of a second carrier doping type (p or n) opposite said first carrier doping type and directly above said second passivation layer such that a pn junction is formed between said junction layer and said second passivation and active layers, said junction creating a depletion region which expands through at least said second passivation layer and said active layer in response to a reverse bias voltage; and
an electrical contact with said first passivating buffer layer such that said buffer layer provides a return current path to said contact.

2. The structure of claim 1, wherein said first passivation buffer layer comprises HgCdTe with Zn, Se, Mn, or other Group II or Group VI materials added to reduce lattice mismatch and misfit dislocations.

3. The structure of claim 1, wherein said structure includes an array of photodiodes and is arranged such that said second passivation and active layers are fully depleted both vertically and laterally when said reverse bias voltage is greater than a predetermined value.

4. The structure of claim 3, said structure arranged such that the reverse bias voltage required to fully deplete said second passivation and active layers both vertically and laterally is given approximately by V=L² q N/2 εε₀, where V is the applied voltage plus the built-in voltage of the pn junction, L is the distance from the pn junction to the farthest extent of the active layer, q is the electronic charge, N is the doping density on the low-doped or undoped side of the junction including the active layer, ε is the relative static dielectric constant of the depleted region of the semiconductor, and ε₀ is the dielectric permittivity of free space.

5. The structure of claim 1, wherein said buffer, active, passivation and junction layers are formed by one or more growth techniques selected from a group consisting of molecular beam epitaxy (MBE), metal organic vapor phase epitaxy, liquid phase epitaxy and solid state recrystalization.

6. The structure of claim 1, wherein said substrate is removed after said buffer, active, passivation and junction layers are formed such that said buffer layer serves as a passivation layer.

7. The structure of claim 1, wherein said structure comprises HgCdTe with Zn, Se, Mn, or other Group II or Group VI materials added to reduce lattice mismatch and misfit dislocations.

8. The structure of claim 1, wherein said second passivation layer and said active layer have respective band gap energies E_{g(pass)} and E_{g(active)}, said second passivation and active layers arranged such that E_{g(pass)}>2*E_{g(active)}.

9. (canceled)

10. The structure of claim 1, further comprising a cap layer of said first carrier doping type between said active layer and said second passivation layer.

11. The structure of claim 1, further comprising a contact layer in electrical contact with said junction layer.

12. The structure of claim 1, wherein said first passivating buffer layer is graded from a wide band gap to a narrower band gap with increasing distance from said substrate.

13. The structure of claim 1, wherein said substrate is optically transparent.

14. The structure of claim 13, further comprising an anti-reflection coating on said substrate.

15. A photodiode structure, comprising:
a substrate;
a buffer layer of a first carrier doping type (n or p) and which is highly-doped through part or all of its thickness above said substrate;
a low-doped or undoped semiconductor active layer of said first carrier doping type above said buffer layer;
a low-doped or undoped passivation layer above said active layer, said passivation layer having a band gap energy graded over at least part of its thickness from that of the active layer to a larger energy; and
a metal layer above said passivation layer such that a Schottky-barrier junction is formed between said metal layer and said passivation and active layers, said junction creating a depletion region which expands through the entirety of both said passivation layer and said active layer in response to a reverse bias voltage.

16. An detector array, comprising:
a substrate;
a first passivating buffer layer of a first carrier doping type (n or p) and which is highly-doped through part or all of its thickness above said substrate;
a low-doped or undoped semiconductor active layer of said first carrier doping type above said buffer layer;
a low-doped or undoped second passivation layer above said active layer, said second passivation layer having a band gap energy graded over at least part of its thickness from that of the active layer to a larger energy;
a junction layer of a second carrier doping type (p or n) opposite said first carrier doping type directly above said second passivation layer; and
an electrical contact with said first passivating buffer layer such that said buffer layer provides a return current path to said contact;
such that an array of pn junctions are formed between said junction layer and said second passivation and active layers, each of said junctions creating a depletion region which expands through at least said second passivation layer and said active layer and extends to the depletion region of all nearest and next nearest neighbor devices in response to a reverse bias voltage.

17. The array of claim 16, wherein said junctions provide respective photocurrents in response to incident infrared light.

18. The array of claim 17, further including external electronic circuitry, optics, and packaging, which receives said photocurrents and provides electrical output signals corresponding to an image formed on said array of junctions from said incident light.

19. A detector array, comprising:
a substrate;
a buffer layer of a first carrier doping type (n or p) and which is highly-doped through part or all of its thickness above said substrate;
a low-doped or undoped semiconductor active layer of said first carrier doping type above said buffer layer;
a low-doped or undoped passivation layer above said active layer, said passivation layer having a band gap energy graded over at least part of its thickness from that of the active layer to a larger energy; and
a reticulated metal or semimetal layer above said passivation layer such that an array of Schottky-barrier junctions are formed between said reticulated metal or semimetal layer and said passivation and active layers, each of said junctions creating a depletion region which expands through the entirety of both said passivation layer and said active layer and extends to the depletion region of all nearest and next nearest neighbor devices in response to a reverse bias voltage.

20. The array of claim 19, wherein said junctions provide respective photocurrents in response to incident infrared light.

21. The array of claim 19, further including external electronic circuitry, optics, and packaging, which receives said photocurrents and provides electrical output signals corresponding to an image formed on said array of junctions from said incident light.

22. A method of forming a photodiode structure, comprising:
providing a substrate;
growing a buffer layer of a first carrier doping type (n or p) and which is highly-doped through part or all of its thickness above said substrate;
growing a low-doped or undoped semiconductor active layer of said first carrier doping type above said buffer layer;
growing a low-doped or undoped passivation layer above said active layer, said passivation layer having a band gap energy graded over at least part of its thickness from that of the active layer to a larger energy;
forming a junction layer directly above said passivation layer such that a pn junction is formed between said junction layer and said passivation and active layers, said junction creating a depletion region which expands through said passivation layer and said active layer in response to a reverse bias voltage; and
forming an electrical contact with said buffer layer such that said buffer layer provides a return current path to said contact.

23. The method of claim 22, wherein said buffer, active, passivation and junction layers are formed by one or more growth techniques selected from a group consisting of molecular beam epitaxy (MBE), metal organic vapor phase epitaxy, liquid phase epitaxy and solid state recrystalization.

24. The method of claim 22, wherein said junction layer is formed by implantation into said passivation layer to form said pn junction.

25. The method of claim 22, further comprising etching said photodiode structure to provide an array of photodiodes and arranging said structure such that said passivation layer is fully depleted both vertically and laterally when said reverse bias voltage is greater than a predetermined value.

26. The method of claim 25, further comprising etching said photodiode structure entirely through said semiconductor active layer and into the highly-doped region of said buffer layer to isolate the photodiodes from each other without the need for lateral extension of the depletion region.

27. The method of claim 26, further comprising passivating the sides of said isolated photodiodes with a wide-band-gap material deposited by evaporation or crystal growth or, as in the case of HgCdTe and other semiconductors for which interdiffusion is a possible processing tool, by indiffusion from a vapor or deposited layer of Cd and/or Zn, or other material appropriate to the semiconductor materials system used, to widen the surface band gap.

28. The method of claim 22, wherein said photodiode structure comprises HgCdTe with Zn, Se, Mn, or other Group II or Group VI materials added to reduce lattice mismatch and misfit dislocations.

29. The method of claim 22, further comprising removing said substrate after said buffer, active, passivation and junction layers are formed such that said buffer layer serves as a passivation layer.

30. The method of claim 22, wherein said passivation layer and said active layer have respective band gap energies E_{g(pass)} and E_{g(active)}, said method further comprising arranging said passivation and active layers such that E_{g(pass)}>2*E_{g(active)}.

31. (canceled)

32. The method of claim 22, further comprising forming a cap layer of said first carrier doping type between said active layer and said passivation layer.

33. The method of claim 22, further comprising forming a contact layer which is in electrical contact with said junction layer.

34. The method of claim 22, further comprising grading said buffer layer from a wide band gap to a narrower band gap with increasing distance from said substrate,

35. A method of forming a photodiode, comprising:
providing a substrate;
growing a buffer layer of a first carrier doping type (n or p) and which is highly-doped through part or all of its thickness above said substrate;
growing a low-doped or undoped semiconductor active layer of said first carrier doping type above said buffer layer;
growing a low-doped or undoped passivation layer above said active layer, said passivation layer having a band gap energy graded over at least part of its thickness from that of the active layer to a larger energy; and
forming a metal layer above said passivation layer such that a Schottky junction is formed between said metal layer and said passivation and active layers, said junction creating a depletion region which expands through said passivation layer and said active layer in response to a reverse bias voltage.
